(19) United States
(12) Patent Application Publication
(10) Pub. No.: US 2026/0358446 A1
(43) Pub. Date: Nov. 12, 2026

(54) ueMeter - Instrument to measure magnetic permeability and electric permittivity of materials

(71) Applicant: Swaresh Borse, Allen, TX (US)

(72) Inventor: Swaresh Borse, Allen, TX (US)

(21) Appl. No.: 19/201,921

(22) Filed: May 8, 2025

(51) Int. Cl. G01R 33/12; G01R 15/00; G01R 15/12; G01R 27/26; G01R 33/00

(52) U.S. Cl. CPC G01R 33/1223; G01R 15/002; G01R 15/125; G01R 27/2641; G01R 33/0023

(57) ABSTRACT

The present invention is an electronic instrument to measure the electric permittivity and magnetic permeability of a material. It makes use of principles of inductance and capacitance to measure magnetic permeability and electric permittivity respectively. Objects built with different materials can be measured for their permeability and permittivity by placing them in appropriate slots of said invention and setting the switch to appropriate selection. Measurements can be viewed on the 7-segment displays on said invention and also more information can be viewed on a computer using said application. This instrument will be applicable in material sciences and electronics fields where properties of materials are required to be measured or calculated.

### CROSS REFERENCE TO RELATED APPLICATIONS

This application does not provide reference to any prior applications.

### BACKGROUND OF THE INVENTION

### 1. Field of Invention

The inductance of a conducting coil depends on the material of its core. A core is typically made of a magnetic material such as iron, ferrite, steel, etc. Every core material has a magnetic permeability which defines its ability to become magnetized in a magnetic field. Magnetic permeability constant is the permeability of free space or vacuum. Relative permeability of a material determines a material's magnetic permeability in relation to that of free space.

The capacitance of a parallel plate capacitor depends on the area of overlap of its conducting plates, distance between the plates and dielectric constant of the insulator separating the plates. Electric permittivity of a material is its ability to store electrical energy. Electric permittivity constant is the permittivity of free space. Relative permittivity of a material determines a material's electric permittivity in relation to that of a free space.

### 2. Description of Related Art

When magnetic material is placed inside the core of a conducting coil, the inductance of coil changes. Such inductors, when connected in an oscillator circuit, produce an AC signal with a frequency that changes when the core material is changed.

When a dielectric material is placed between two parallel conductive plates, it forms a capacitor. The capacitance changes with dielectric material changes. Such capacitors, when connected in an oscillator circuit, produce an AC signal with a frequency that changes when the dielectric material is changed.

The output of the above-mentioned oscillators can be fed to a frequency-to-voltage converter which converts the incoming oscillator frequency signals to output voltage signals. This way each material can be tested for its relative permittiviy and relative permeability.

### SUMMARY OF THE INVENTION

The present invention is based on the working principles of inductors and capacitors. Changes in core material of a coil changes the value of inductance. Similarly, changes in dielectric material of a capacitor changes the value of capacitance. These phenomena are used to determine the values of electric permittivity and magnetic permeability of different materials. The materials to be tested can be used as core for an inductor or a dielectric for capacitance. The inductance and capacitance values are processed by a micro-controller to produce readable outputs of electric permittivity and magnetic permeability.

### BRIEF DESCRIPTION OF INVENTION DRAWINGS

FIG. 1. Block Diagram

FIG. 2. Mechanical Construction

FIG. 3. Overall view finished instrument

### DETAILED DESCRIPTION OF INVENTION

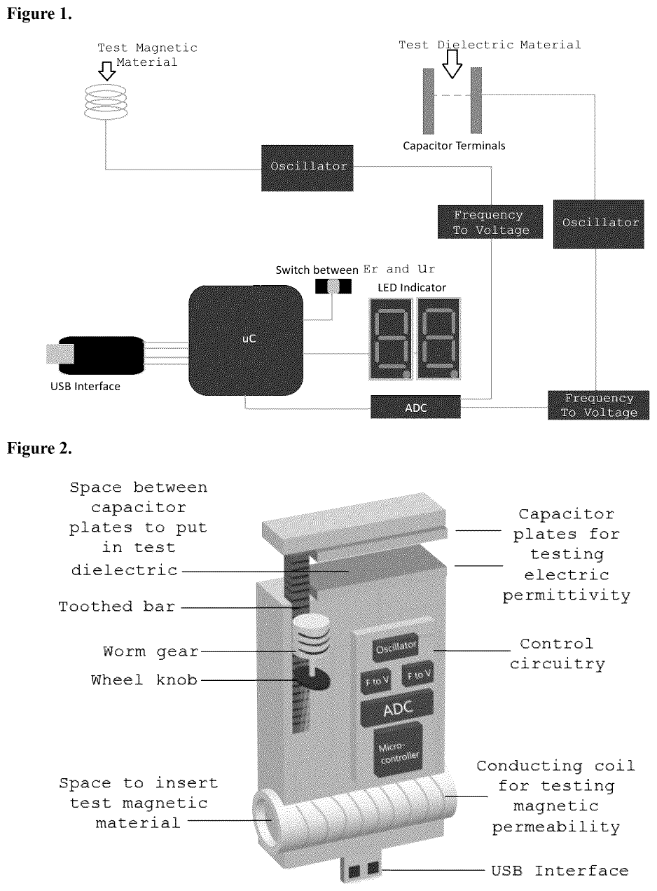

The present invention uses working principles of a capacitor and an inductor. FIG. 1 of invention drawings shows a block diagram of said invention.

A conducting coil with an air core is used to determine the relative magnetic permeability of material to be tested. Said conducting coil with an inductance value of ‘L’ is connected in an oscillator circuit. Value ‘L’ of inductance is described by the following equation:

L=μᵣμ₀*N²* A_{L}/l (1)

Where,

L: Value of inductance

μᵣ: Relative magnetic permeability of core material

μ₀: Absolute magnetic permeability of free space

N: No. of turns in coil

A_{L}: Cross section area of coil

l: Length of coil

Said oscillator circuit generates a frequency of value ‘F_{L}’ which is described by the following equation:

F_{L}=f(L)→F_{L}=f(μᵣ) (2)

The output of said oscillator circuit is connected to a frequency-to-voltage converter. Said frequency-to-voltage converter generates a voltage of value ‘V_{L}’ which is described by the following equation:

V_{L}=f(F_{L})→V_{L}=f(μᵣ)→μᵣ=f(V_{L}). (3)

Equation 3 above implies that relative magnetic permeability of core material used in said coil is function of output voltage of said frequency-to-voltage converter.

For air core (free space) value of ur is equal to 1.

When a magnetic material with relative magnetic permeability value of μᵣ′ is inserted in the core space of the coil, its inductance changes. The said air core is replaced by said magnetic material. The equation 3 above now gets modified to the below:

μᵣ′=f(V_{L}1) (4)

Where,

μᵣ′: Relative magnetic permeability of core material

V_{L}1: New output voltage of frequency-to-voltage converter when a core material of μᵣ′ is used

A parallel plate capacitor with air as dielectric material is used to determine the relative electric permittivity of a material to be tested. Said parallel plates of capacitor are separated by an adjustable distance ‘d’. Said parallel plate capacitor is connected in an oscillator circuit. Value ‘C’ of capacitance is described by the following equation:

C=εᵣ* ε₀*A_{C}/d (5)

Where,

C: Value of capacitance

εᵣ: Relative electric permittivity of dielectric medium

ε₀: Absolute electric permittivity of free space

A_{C}: Overlapping area of said parallel plates

d: Adjustable distance between said parallel plates

Said oscillator circuit generates a frequency of value ‘F_{C}’ which is described by the following equation:

F_{C}=f(C)→F=f(εᵣ, d) (6)

The output of said oscillator circuit is connected to a frequency-to-voltage converter. Said frequency-to-voltage converter generates a voltage of value ‘Vc’ which is described by the following equation:

V_{C}=f(F_{C})→Vc=f(εᵣ, d)→εᵣ=f(V_{C}, d) (7)

Equation 7 above implies that relative electric permittivity of dielectric material used in said capacitor is function of output voltage of said frequency-to-voltage converter and the distance between said parallel plates.

For air core (free space) value of εᵣ is equal to 1.

When an insulator material with a relative electric permittivity value of εᵣ′ is inserted in the dielectric space of said capacitor, its capacitance changes. The said air dielectric space is replaced by said insulator material. The equation 7 above now gets modified to the below:

εᵣ′=f(V_{C}1) (8)

Where,

εᵣ′: Relative electric permittivity of insulator material

V_{C}1: New output voltage of frequency-to-voltage converter when an insulator material of εᵣ′ is used

Outputs of the two said frequency-to-voltage converters are fed as inputs to an analog-to-digital converter. The output of said analog-to-digital converter is fed to a micro-controller for processing to measure and display the relative electric permittivity and relative magnetic permeability of test materials used. Said invention also supports serial-to-USB interface for use with computing devices with application software to review more information about the materials at test.

FIG. 2 of invention drawings shows the interior of said invention. It holds a circuit board to house all relevant electronic components. The distance between plates of said parallel plate capacitor is adjustable with the help of worm gear and toothed bar. Said worm gear is connected to a wheel knob for ease of user's operation. FIG. 2 of invention drawings also shows said conducting coil wrapped around a cylindrical chassis.

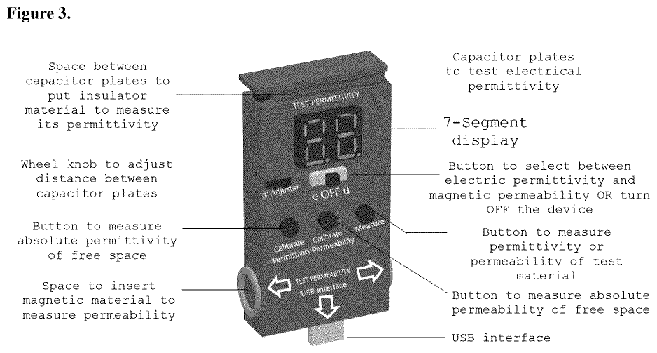

FIG. 3 of invention drawings illustrates the overall look of said invention as an instrument. It shows a 7-segment display that will be used to display the measured values of relative electric permittivity and relative magnetic permeability. It also shows said wheel knob for distance adjustments between said capacitor plates. Said invention also has a button to select between permittivity, permeability or turn said instrument OFF. FIG. 3 also shows ‘Calibrate Permittivity’ and ‘Calibrate Permeability’ buttons used for measuring voltage at output of said frequency-to-voltage converters reflecting the absolute electric permittivity and absolute magnetic permeability of free space/air respectively for reference. The ‘Measure’ button is used to measure relative electric permittivity or relative magnetic permeability of test materials. FIG. 3 also shows said USB interface at the bottom of said invention.

The invention claimed is:

1. An electronic instrument comprising:
two oscillators, two frequency-to-voltage converters, one two-channel analog-to-digital converter (ADC), one micro-controller, one serial-to-USB converter and two 7-segment LED displays, wherein output of one of said oscillators is connected to one of said frequency-to-voltage converters and output of second one of said oscillators is connected to second one of said frequency-to-voltage converters, output of said one of frequency-to-voltage converters is fed as an input to one of the channels of said two-channel ADC, output of said second one of frequency-to-voltage converters is fed as an input to second one of the channels of said two-channel ADC, output of said ADC is fed as an input to said micro-controller;
and said micro-controller is interfaced with said two 7-segment displays, a switch to select between magnetic permeability and electric permittivity options, and a serial-to-USB device for interfacing said invention with computing devices.
